(19) United States
(12) Patent Application Publication
(10) Pub. No.: US 2023/0049907 A1
(43) Pub. Date: Feb. 16, 2023

(54) LIGHT EMITTING DISPLAY APPARATUS AND METHOD OF MANUFACTURING THE SAME

(71) Applicant: LG Display Co., Ltd., Seoul (KR)

(72) Inventors: Hye Rin KIM, Paju-si (KR); Dae Kyu KIM, Paju-si (KR); Dae Sung JUNG, Paju-si (KR); Jeong Ho KIM, Paju-si (KR)

(21) Appl. No.: 17/884,479

(22) Filed: Aug. 9, 2022

(30) Foreign Application Priority Data
Aug. 10, 2021 (KR) 10-2021-0105693

(51) Int. Cl. H01L 27/32

(52) U.S. Cl. CPC H01L 27/3276; H01L 27/3213

(57) ABSTRACT

A light emitting display apparatus and a method of manufacturing the same are provided. The light emitting display apparatus includes a display panel including a display area and a non-display area, a first reference line arranged in a first direction in the display area, a second reference line arranged in a second direction transverse the first direction in the display area and electrically connected to the first reference line, and a power line arranged in the first direction in the display area and disposed between at least two of the first reference lines. A pattern density is reduced and a problem where a line interval increases is solved in implementing a narrow bezel and a large screen of a display panel on the basis of mesh-type reference lines provided in a display area and a power line disposed therebetween, and a problem where a second source voltage increases (EVSS rising) is minimized or reduced, thereby realizing a uniform image without a position-based luminance difference and a color coordinate difference.

### CROSS-REFERENCE TO RELATED APPLICATIONS

This application claims the benefit of the Korean Patent Application No. 10-2021-0105693 filed on Aug. 10, 2021, in the Korean Intellectual Property Office, which is hereby incorporated by reference as if fully set forth herein.

### BACKGROUND

### Technical Field

The present disclosure relates to a light emitting display apparatus and a method of manufacturing the same.

### Description of the Related Art

As information technology advances, the market for display apparatuses which are connection mediums connecting a user to information is growing. Therefore, the use of display apparatuses such as light emitting display apparatuses, quantum dot display (QDD) apparatuses, and liquid crystal display (LCD) apparatuses is increasing.

The display apparatuses described above include a display panel which includes a plurality of subpixels, a driver which outputs a driving signal for driving the display panel, and a power supply which supplies power to the display panel or the driver.

In such display apparatuses, when the driving signal (for example, a scan signal and a data signal) is supplied to each of the subpixels provided in the display panel, a selected subpixel may transmit light or may self-emit light, and thus, an image may be displayed.

### BRIEF SUMMARY

To overcome problems of the related art, the present disclosure may provide a light emitting display apparatus and a method of manufacturing the same, in which a pattern density is reduced and a problem where a line interval increases is solved in implementing a narrow bezel and a large screen of a display panel on the basis of mesh-type reference lines provided in a display area and a second power line disposed therebetween. A problem where a second source voltage increases (EVSS rising) is minimized or reduced, thereby realizing a uniform image without a position-based luminance difference and a color coordinate difference.

To achieve these benefits and other advantages and in accordance with the purpose of the disclosure, as embodied and broadly described herein, a light emitting display apparatus includes a display panel including a display area and a non-display area, a first reference line arranged in a first direction in the display area, a second reference line arranged in a second direction transverse the first direction in the display area and electrically connected to the first reference line, and a power line arranged in the first direction in the display area and disposed between at least two of the first reference lines.

At least one of the first reference line and the second reference line may be disposed on a layer which differs from the power line.

The second reference line may be disposed on a layer which differs from the first reference line and the power line.

The first reference line and the power line may be disposed in a source drain metal layer that is in a transistor included in a subpixel of the display panel.

The second reference line may be disposed in a semiconductor layer that is in a transistor included in a subpixel of the display panel.

The first reference line and the power line may be disposed between an interlayer insulation layer and a planarization layer disposed on a layer which is higher than the second reference line.

The second reference line may be disposed between a buffer layer and a gate insulation layer disposed on a layer which is lower than the first reference line and the power line.

The power line may comprise a lower level power line. A power level of the lower level power line may be lower than a predetermined or selected power level.

The light emitting display apparatus further may comprise another power line whose power level may be higher than the predetermined or selected power level.

The first reference line and the second reference line may be arranged as a mesh type.

The power line may be disposed to have a mesh shape in the display area.

In another embodiment of the present disclosure, a light emitting display apparatus includes a buffer layer disposed on a substrate, a lower reference line in a semiconductor layer disposed on the buffer layer and arranged in a horizontal direction in a display area of the substrate, at least one insulation layer disposed on the lower reference line, an upper reference line disposed on the at least one insulation layer, arranged in a vertical direction in the display area of the substrate, and electrically connected to the lower reference line, and a power line disposed on the at least one insulation layer and arranged in the vertical direction in the display area of the substrate.

The upper reference line and the power line may be disposed apart from each other on the at least one insulation layer and may each include a source drain metal layer.

In another embodiment of the present disclosure, a method of manufacturing a light emitting display apparatus includes forming a buffer layer on a substrate, forming a lower reference line in a semiconductor layer disposed on the buffer layer and arranged in a horizontal direction in a display area of the substrate, forming at least one insulation layer on the lower reference line, patterning a first source drain metal layer disposed on the at least one insulation layer and arranged in a vertical direction in the display area of the substrate to form an upper reference line electrically connected to the lower reference line, and patterning a second source drain metal layer disposed on the at least one insulation layer and arranged in the vertical direction in the display area of the substrate to form a power line apart from the upper reference line.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a block diagram schematically illustrating a light emitting display apparatus;

FIG. 2 is a block diagram schematically illustrating a subpixel illustrated in FIG. 1;

FIGS. 3A and 3B are a diagram illustrating an arrangement example of a scan driver of a gate-in panel (GIP) type;

FIGS. 4 and 5 are diagrams of a configuration of an apparatus related to the scan driver of the GIP type;

FIG. 6 is a diagram illustrating a shape of a display panel;

FIG. 7 is a diagram illustrating a circuit configuration of a subpixel;

FIG. 8 is a plan view illustrating a reference line and a second power line connected to three subpixels according to a first embodiment of the present disclosure;

FIGS. 9A and 9B are a plan view for describing a comparison of an arrangement structure according to the first embodiment with an experiment example;

FIG. 10 is a plan view illustrating various signal lines and a second power line connected to a plurality of subpixels according to the first embodiment of the present disclosure;

FIG. 11 is a plan view illustrating a reference line and a second power line connected to three subpixels according to a second embodiment of the present disclosure;

FIG. 12 is a plan view illustrating various signal lines and a second power line connected to a plurality of subpixels according to the second embodiment of the present disclosure;

FIG. 13 is a cross-sectional view illustrating a region A1-A2 of FIG. 12;

FIG. 14 is a cross-sectional view illustrating a region B1-B2 of FIG. 12;

FIG. 15 is a cross-sectional view illustrating a region C1-C2 of FIG. 12;

FIGS. 16A, 16B and 17 are diagrams for describing an arrangement structure of a line according to an embodiment of the present disclosure and an advantage based thereon; and

FIGS. 18A, 18B and 19 are diagrams for describing an arrangement structure of a line according to an experiment example and a disadvantage based thereon.

### DETAILED DESCRIPTION

Hereinafter, the present disclosure will be described more fully with reference to the accompanying drawings, in which embodiments of the disclosure are shown. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art.

A display apparatus according to the present disclosure may be applied to televisions (TVs), video players, personal computers (PCs), home theaters, electronic devices for vehicles, and smartphones, but is not limited thereto. The display apparatus according to the present disclosure may be implemented as a light emitting display apparatus, a quantum dot display (QDD) apparatus, or a liquid crystal display (LCD) apparatus. Hereinafter, however, for convenience of description, a light emitting display apparatus self-emitting light on the basis of an inorganic light emitting diode or an organic light emitting diode will be described for example.

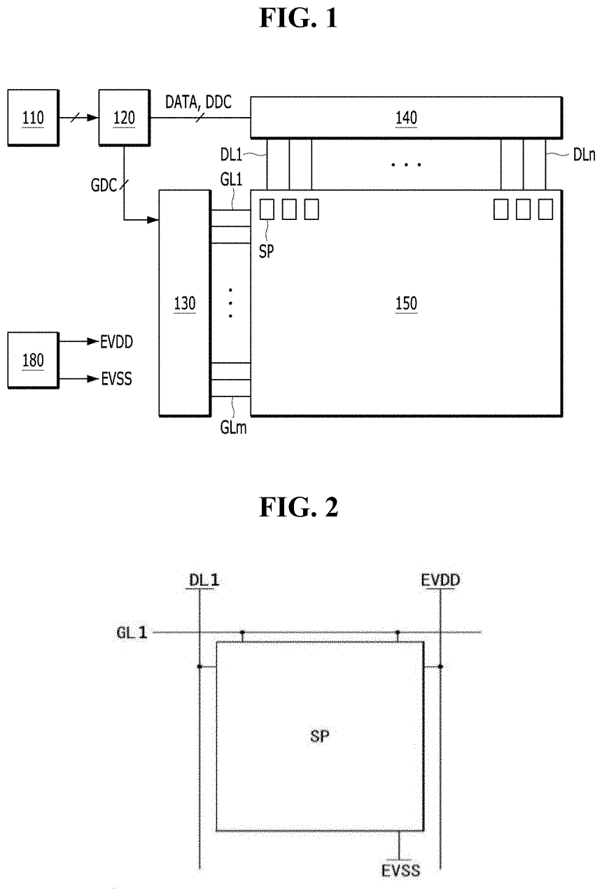

FIG. 1 is a block diagram schematically illustrating a light emitting display apparatus, and FIG. 2 is a block diagram schematically illustrating a subpixel illustrated in FIG. 1.

As illustrated in FIGS. 1 and 2, the light emitting display apparatus may include a video supply unit or circuit 110, a timing controller 120, a scan driver 130, a data driver 140, a display panel 150, and a power supply 180.

The video supply unit 110 (or a set or a host system) may output a video data signal supplied from the outside or a video data signal and various driving signals stored in an internal memory thereof. The video supply unit 110 may supply a data signal and the various driving signals to the timing controller 120.

The timing controller 120 may output a gate timing control signal GDC for controlling an operation timing of the scan driver 130, a data timing control signal DDC for controlling an operation timing of the data driver 140, and various synchronization signals (for example, a vertical synchronization signal Vsync and a horizontal synchronization signal Hsync). The timing controller 120 may provide the data driver 140 with the data timing control signal DDC and a data signal DATA supplied from the video supply unit 110. The timing controller 120 may be implemented as an integrated circuit (IC) type and may be mounted on a printed circuit board (PCB), but is not limited thereto.

The scan driver 130 may output a scan signal (or a scan voltage) in response to the gate timing control signal GDC supplied from the timing controller 120. The scan driver 130 may supply the scan signal to a plurality of subpixels, included in the display panel 150, through a plurality of scan lines GL1 to GLm. The scan driver 130 may be implemented as an IC type or may be directly provided on the display panel 150 in a gate-in panel (GIP) type, but is not limited thereto.

In response to the data timing control signal DDC supplied from the timing controller 120, the data driver 140 may sample and latch the data signal DATA, convert a digital data signal into an analog data voltage on the basis of a gamma reference voltage, and output the analog data voltage. The data driver 140 may respectively supply data voltages to the subpixels of the display panel 150 through a plurality of data lines DL1 to DLn. The data driver 140 may be implemented as an IC type or may be mounted on the display panel 150 or a PCB, but is not limited thereto.

The power supply 180 may generate a first driving power having a high level and a second driving power having a low level on the basis of an external input voltage supplied from the outside and may respectively output the first driving power and the second driving power through a first power line EVDD and a second power line EVSS. The high level is higher than the low level. The low level is lower than a predetermined or selected power level. The high level is higher than the predetermined or selected power level. The power supply unit 180 may generate a voltage (for example, a gate voltage including a gate high voltage and a gate low voltage) needed for driving of the scan driver 130 or a voltage (for example, a drain voltage and a half drain voltage) needed for driving of the data driver 140, in addition to the first driving power and the second driving power.

The display panel 150 may display an image on the basis of a driving signal including the scan signal and a data voltage, the first driving power, and the second driving power. The subpixels of the display panel 150 may each self-emit light. The display panel 150 may be manufactured based on a substrate, having stiffness or flexibility, such as glass, silicon, or polyimide. Also, the subpixels emitting light may include pixels including red, green, and blue, or may include pixels including red, green, blue, and white.

For example, one subpixel SP may be connected to a first data line DL1, a first gate line GL1, the first power line EVDD, and the second power line EVSS and may include a pixel circuit which includes a switching transistor, a driving transistor, a storage capacitor, and an organic light emitting diode. The subpixel SP applied to the light emitting display apparatus may self-emit light, and thus, may be complicated in circuit configuration. Also, the subpixel SP may further include various circuits such as a compensation circuit which compensates for a degradation in the organic light emitting diode emitting light and a degradation in the driving transistor supplying a driving current to the organic light emitting diode. Accordingly, it can be seen in figures that the subpixel SP is simply illustrated in a block form.

Hereinabove, each of the timing controller 120, the scan driver 130, and the data driver 140 has been described as an individual element. However, based on an implementation type of the light emitting display apparatus, one or more of the timing controller 120, the scan driver 130, and the data driver 140 may be integrated into one IC.

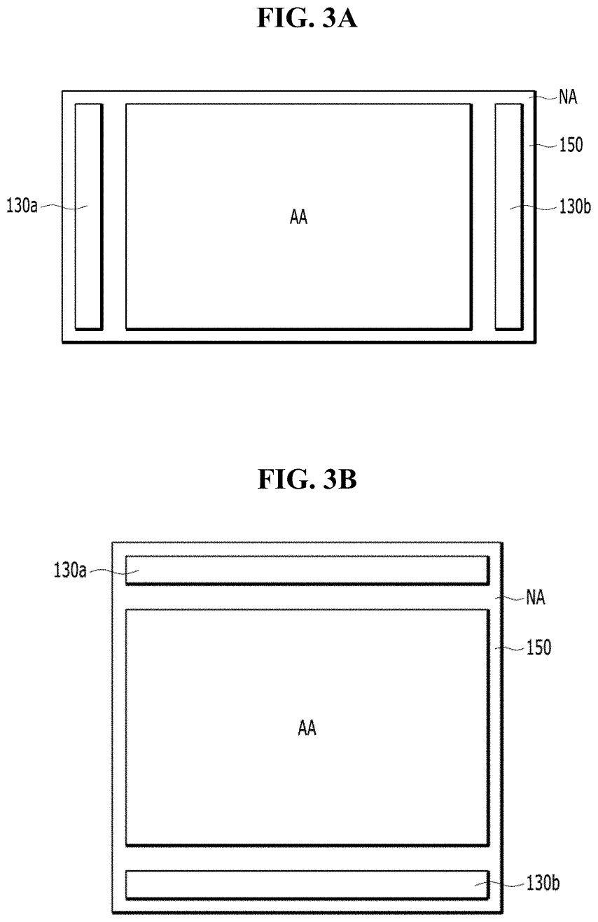

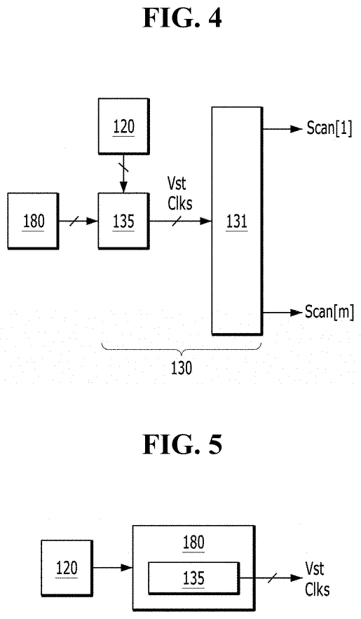

FIGS. 3A and 3B are diagrams illustrating an arrangement example of a scan driver of a GIP type, and FIGS. 4 and 5 are diagrams of a configuration of an apparatus related to the scan driver of the GIP type.

As illustrated in FIGS. 3A and 3B, a plurality of GIP type scan drivers 130a and 130b may be disposed in a non-display area NA of a display panel 150. The scan drivers 130a and 130b, as in FIG. 3A, may be disposed in left and right non-display areas NA of the display panel 150. Also, as in FIG. 3B, the scan drivers 130a and 130b may be disposed in upper and lower non-display areas NA of the display panel 150.

An example is illustrated and described where the scan drivers 130a and 130b are disposed in left and right or upper and lower non-display areas NA, but the scan drivers 130a and 130b may be disposed in only one of the left, right, upper, and lower non-display areas NA instead of on two sides as shown in FIGS. 3A and 3B.

As illustrated in FIG. 4, a GIP type scan driver 130 may include a shift register 131 and a level shifter 135. The level shifter 135 may generate clock signals Clks and a start signal Vst on the basis of signals and voltages output from a timing controller 120 and a power supply 180. The clock signals Clks may be generated in a K-phase form (where K is an integer of 2 or more) where phases such as two phases, four phases, or eight phases differ.

The shift register 131 may operate based on the signals Clks and Vst output from the level shifter 135 and may output scan signals Scan[1] to Scan[m] for turning on/off transistors provided in a display panel. The shift register 131 may be implemented as a thin film type on the display panel on the basis of the GIP type. Accordingly, the scan drivers 130a and 130b provided in the non-display area NA of the display panel 150 illustrated in FIG. 3 may correspond to the shift register 131.

As illustrated in FIGS. 4 and 5, unlike the shift register 131, the level shifter 135 may be independently implemented as an IC type or may be included in the power supply 180. However, this may be merely an embodiment, and the present disclosure is not limited thereto.

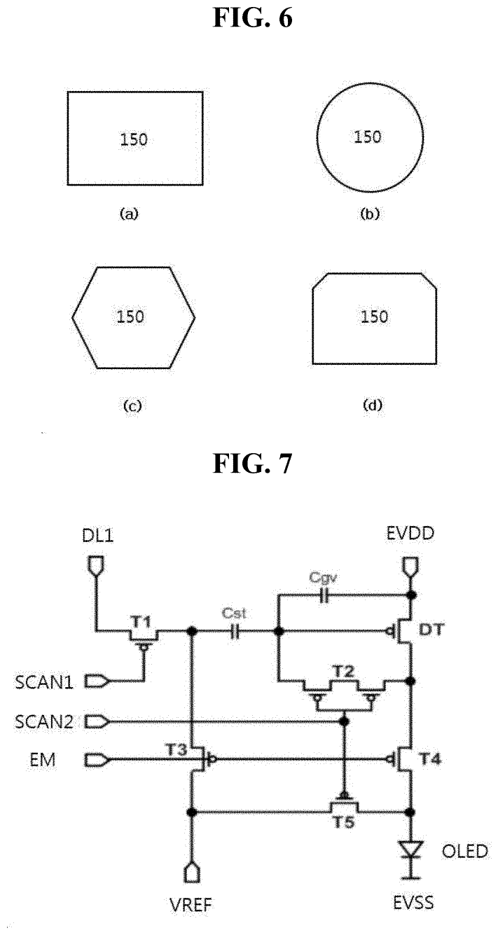

FIG. 6 is a diagram illustrating a shape of a display panel, and FIG. 7 is a diagram illustrating a circuit configuration of a subpixel.

As illustrated in FIG. 6, a display panel 150 may be implemented in various shapes such as a rectangular shape (or a tetragonal shape) ((a) of FIG. 6), a circular shape ((b) of FIG. 6), an oval shape ((c) of FIG. 6), and a hexagonal shape ((d) of FIG. 6). Except for a rectangular-shape display panel 150 widely used as in (a) of FIG. 6, display panels 150 of (b) of FIG. 6 to (d) of FIG. 6 may have shapes (shapes which differ from a general shape) which differ from a conventional shape, and thus, may be referred to as a different-shape display panel.

As illustrated in FIG. 7, a subpixel may include five switching transistors (for example, first, second, third, fourth and fifth switching transistors) T1, T2, T3, T4, T5, one driving transistor DT, one storage capacitor Cst, and one light emitting diode OLED. Here, optional compensation capacitor Cgv as shown in FIG. 7 may be a compensation capacitor provided for compensation and may be omitted.

The first switching transistor T1 may transfer a data voltage, applied through a first data line DL1, to a first electrode of the storage capacitor Cst in response to a first scan signal applied through a first scan line SCAN1.

The second switching transistor T2 may electrically connect a gate electrode of the driving transistor DT to a second electrode thereof (allow the driving transistor DT to be in a connection state so as to compensate for a threshold voltage) in response to a second scan signal applied through a second scan line SCAN2.

The third switching transistor T3 may transfer a reference voltage (an initialization voltage or a compensation voltage), applied through a reference line VREF, to the first electrode of the storage capacitor Cst in response to an emission control signal (or a third scan signal) applied through an emission control line (or a third scan line) EM.

The fourth switching transistor T4 may transfer a driving current, generated from the driving transistor DT, to an anode electrode of the light emitting diode OLED in response to the emission control signal applied through the emission control line EM.

The storage capacitor Cst may store a data voltage and may drive the driving transistor DT on the basis of the stored data voltage. The light emitting diode OLED may emit light on the basis of the driving current generated from the driving transistor DT.

The subpixel illustrated in FIG. 7 may compensate for a threshold voltage of the driving transistor DT on the basis of the second and third switching transistors T2 and T3 and may control an emission time of the light emitting diode OLED on the basis of the fourth switching transistor T4, and thus, may have various advantages.

Furthermore, in FIG. 7, an example where all of thin film transistors included in a subpixel are implemented as a P type has been described. However, all of thin film transistors included in a subpixel may be implemented as an N type or in a structure where the P type and the N type are mixed. In addition, FIG. 7 is merely illustrated and described for helping understand a planar structure and a cross-sectional structure of power lines and various signal lines connected to a subpixel in conjunction with the following embodiment, and the present disclosure is not limited thereto.

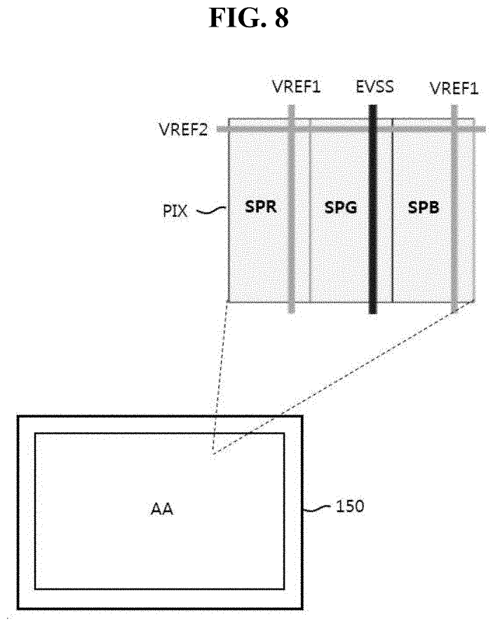

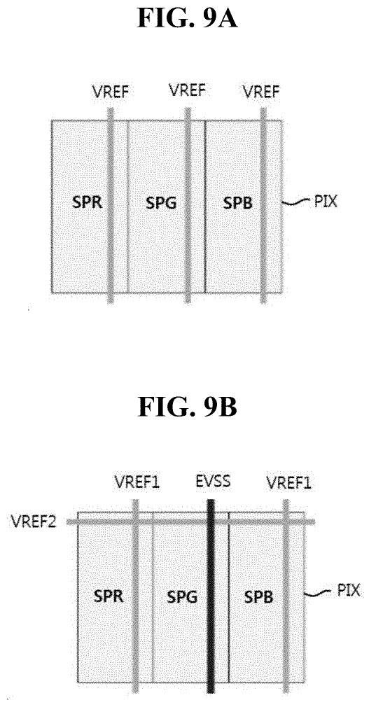

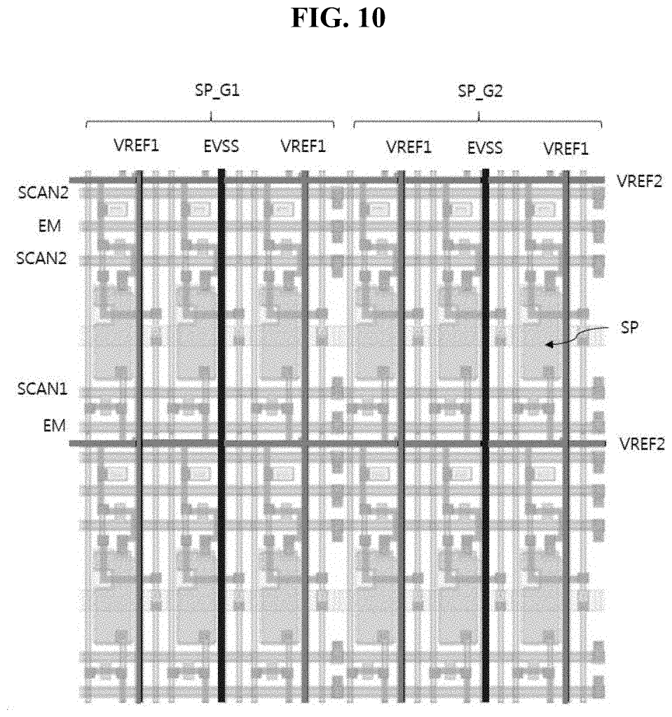

FIG. 8 is a plan view illustrating a reference line and a second power line connected to three subpixels according to a first embodiment of the present disclosure, FIGS. 9A and 9B are a plan view for describing a comparison of an arrangement structure according to the first embodiment with an experiment example, and FIG. 10 is a plan view illustrating various signal lines and a second power line connected to a plurality of subpixels according to the first embodiment of the present disclosure.

As illustrated in FIG. 8, according to the first embodiment, a pixel PIX where a red subpixel SPR, a green subpixel SPG, and a blue subpixel SPB are arranged in order may be disposed in the display area AA of the display panel 150. The arrangement order of subpixels arranged in the pixel PIX may be merely an embodiment, but the present disclosure is not limited thereto.

Moreover, a first reference line VREF1 arranged in a first direction (e.g., lengthwise), a second reference line VREF2 arranged in a second direction (e.g., widthwise), and a second power line EVSS arranged in the first direction may be provided in the display area AA of the display panel 150. The first reference line VREF1 and the second reference line VREF2 may be arranged as a mesh type.

According to the first embodiment, the first reference line VREF1 and the second reference line VREF2 may be disposed on a layer which differs from the second power line EVSS. The first reference line VREF1 and the second reference line VREF2 may be disposed on the same layer so as to be electrically connected to each other.

According to the second embodiment, the second reference line VREF2 may be disposed on a layer which differs from the first reference line VREF1 and the second power line EVSS. The second reference line VREF2 may be electrically connected to the first reference line VREF1, and this may be an overlap region therebetween.

Comparing the experiment example of FIG. 9A with the first embodiment of FIG. 9B, in the present disclosure, it may be seen that the second reference line VREF2 arranged in the second direction is further disposed and one of the reference lines VREF arranged in the first direction is replaced with the second power line EVSS, and accordingly, an arrangement structure of lines is modified compared to the experiment example.

As illustrated in FIG. 10, according to the first embodiment, each of second power lines EVSS may be disposed between two adjacent first reference lines VREF1. This may be seen through an arrangement relationship where two first reference line VREF1 are horizontally symmetric with one second reference line VREF2, with respect to a virtual vertical line which divides a subpixel SP_G1 of a first group and a subpixel SP_G2 of a second group.

FIG. 10 illustrates an arrangement relationship between the second power line EVSS and various signal lines VREF1, VREF2, SCAN1, SCAN2, and EM connected to a plurality of subpixels on the basis of the subpixel illustrated and described in FIG. 7. Based thereon, two second scan lines SCAN2, two emission control lines EM, and one first scan line SCAN1 may be arranged between two second reference lines VREF2. Also, each subpixel SP may be electrically connected to the signal lines VREF1, VREF2, SCAN1, SCAN2, and EM and the second power line EVSS disposed adjacent to the signal lines.

As described above, comparing with the experiment example, various effects may be obtained by modifying an arrangement structure of lines as in the first embodiment, and this will be described after a second embodiment is described.

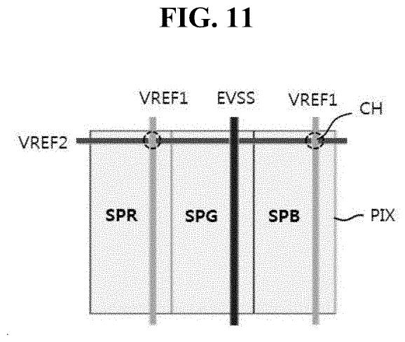

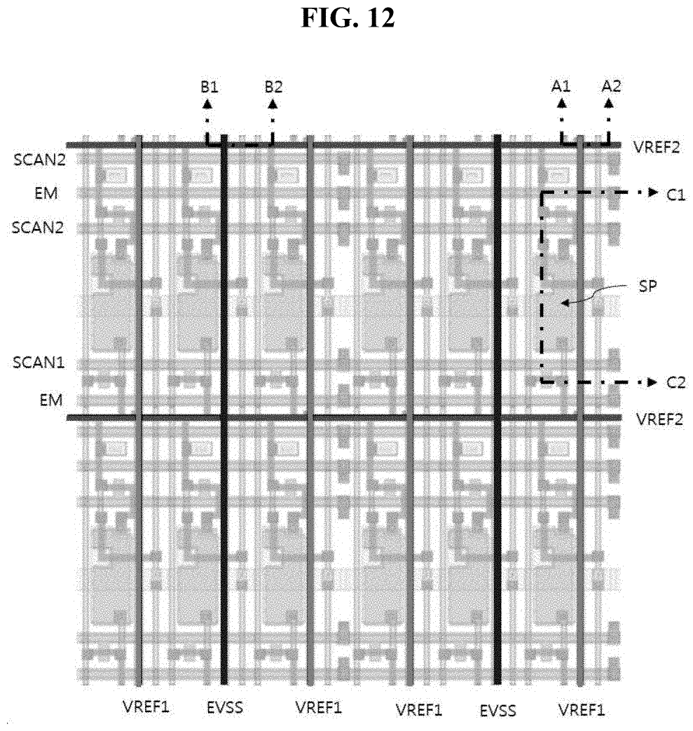

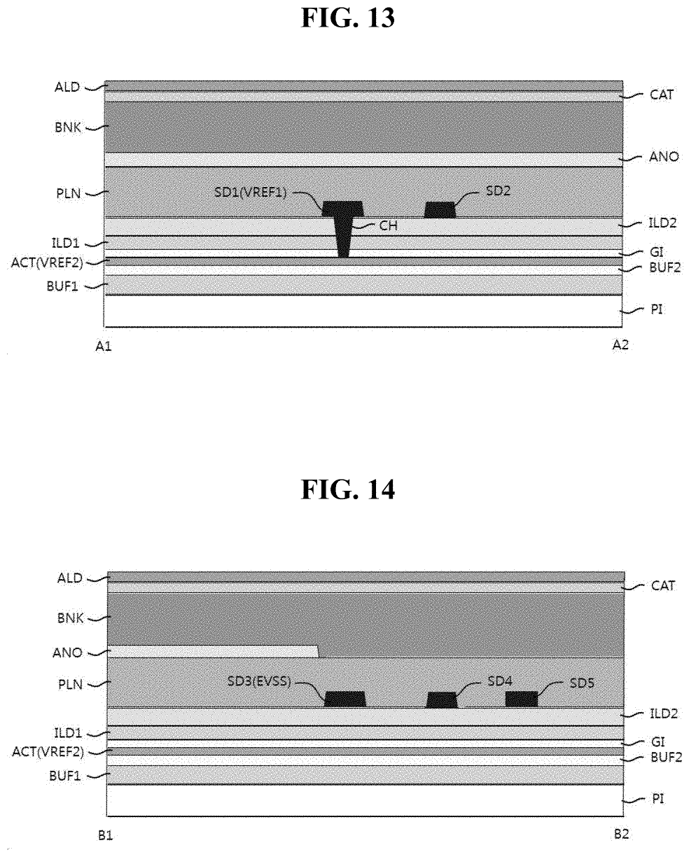

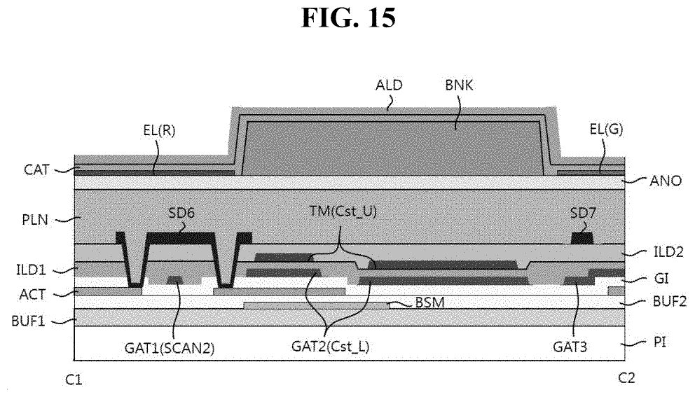

FIG. 11 is a plan view illustrating a reference line and a second power line connected to three subpixels according to a second embodiment of the present disclosure, FIG. 12 is a plan view illustrating various signal lines and a second power line connected to a plurality of subpixels according to the second embodiment of the present disclosure, FIG. 13 is a cross-sectional view illustrating a region A1-A2 of FIG. 12, FIG. 14 is a cross-sectional view illustrating a region B1-B2 of FIG. 12, and FIG. 15 is a cross-sectional view illustrating a region C1-C2 of FIG. 12.

As illustrated in FIG. 11, according to the second embodiment, a pixel PIX where a red subpixel SPR, a green subpixel SPG, and a blue subpixel SPB are arranged in order may be disposed in a display area AA of a display panel 150. The arrangement order of subpixels arranged in the pixel PIX may be merely an embodiment, but the present disclosure is not limited thereto.

Moreover, a first reference line VREF1 arranged in a first direction (e.g., lengthwise), a second reference line VREF2 arranged in a second direction (e.g., widthwise), and a second power line EVSS arranged in the first direction may be provided in the display area AA of the display panel 150. The first reference line VREF1 and the second reference line VREF2 may be arranged as a mesh type.

The second reference line VREF2 may be disposed on a layer (a lower layer) which is lower than the first reference line VREF1 and the second power line EVSS. The second reference line VREF2 may be electrically connected to the first reference line VREF1 through a contact hole CH.

The first reference line VREF1 and the second power line EVSS may be disposed on the same layer and may be formed by a source drain metal layer which configures a source electrode and a drain electrode of a transistor included in a subpixel SP. Also, the second reference line VREF2 may be formed by (e.g., formed in or formed of) a semiconductor layer which configures an active area of the transistor included in the subpixel SP. Hereinafter, relevant descriptions will be given in more detail with reference to FIGS. 12 to 15.

As illustrated in FIGS. 12 and 13, a first buffer layer BUF1 may be disposed on a substrate (or a film) PI. The first buffer layer BUF1 may be formed of a multilayer. A second buffer layer BUF2 may be disposed on the first buffer layer BUF1.

A semiconductor layer ACT may be disposed on the second buffer layer BUF2. The semiconductor layer ACT may include a portion of the second reference line VREF2. The semiconductor layer ACT including the second reference line VREF2 may be disposed on a layer which is lower than the first reference line VREF1, and thus, may be referred to as a lower reference line. A gate insulation layer GI may be disposed on the semiconductor layer ACT. A first interlayer insulation layer ILD1 may be disposed on the gate insulation layer GI. A second interlayer insulation layer ILD2 may be disposed on the first interlayer insulation layer ILD1.

A first source drain metal layer SD1 and a second source drain metal layer SD2 may be disposed on the second interlayer insulation layer ILD2. The first source drain metal layer SD1 and the second source drain metal layer SD2 may be disposed apart from each other. The first source drain metal layer SD1 may be a portion which configures the first reference line VREF1, and the second source drain metal layer SD2 may be a portion which configures a data line of an adjacent subpixel. The first source drain metal layer SD1 configuring the first reference line VREF1 may be disposed on a layer which is higher than the second reference line VREF2, and thus, may be referred to as an upper reference line.

A planarization layer PLN may be disposed on the second interlayer insulation layer ILD2. The planarization layer PLN may be selected as a material which covers the first source drain metal layer SD1 and the second source drain metal layer SD2 and planarizes a surface.

An anode electrode layer ANO may be disposed on the planarization layer PLN. The anode electrode layer ANO may be selected as an anode electrode of an organic light emitting diode. A bank layer BNK may be disposed on the anode electrode layer ANO. The bank layer BNK may divide or separate subpixels from each other. A cathode electrode layer CAT may be disposed on the bank layer BNK. The cathode electrode layer CAT may be selected as a cathode electrode of the organic light emitting diode.

A passivation layer ALD may be disposed on the cathode electrode layer CAT. The passivation layer ALD may be formed in a dense medium form by a deposition process for forming a layer by atom units. Another layer such as an organic/inorganic complex layer may be further disposed on the passivation layer ALD.

As illustrated in FIGS. 12 to 14, a third source drain metal layer SD3, a fourth source drain metal layer SD4, and a fifth source drain metal layer SD5 may be disposed on the second interlayer insulation layer ILD2.

The third source drain metal layer SD3 may be a portion which configures the second power line EVSS, and each of the fourth source drain metal layer SD4 and the fifth source drain metal layer SD5 may be a portion which configures a data line of an adjacent subpixel.

As illustrated in FIGS. 12 to 15, a light blocking layer BSM may be disposed on the first buffer layer BUF1. The light blocking layer BSM may block the irradiation of external light onto the semiconductor layer ACT of the transistor (particularly, a semiconductor layer of a driving transistor). The light blocking layer BSM may be selected as a metal layer for decreasing the absorption or transmission of light. The second buffer layer BUF2 may be selected as a material for planarizing a surface of the first buffer layer BUF1 where the light blocking layer BSM is formed. The semiconductor layer ACT configuring an active layer of the transistor may be disposed on the second buffer layer BUF2. A first gate metal layer GAT1, a second gate metal layer GAT2, and a third gate metal layer GAT3 may be disposed on the gate insulation layer GI. The first gate metal layer GAT1 may be a portion which configures the second scan line SCAN2. The second gate metal layer GAT2 may be a portion which configures a lower electrode Cst L of the storage capacitor Cst. The third gate metal layer GAT3 may be a portion which configures a gate electrode of the transistor.

A metal layer TM may be disposed on the first interlayer insulation layer ILD1. The metal layer TM may be a portion which configures an upper electrode Cst U of the storage capacitor Cst. The metal layer TM may be disposed to correspond to the second gate metal layer GAT2, for forming the storage capacitor Cst.

A sixth source drain metal layer SD6 and a seventh source drain metal layer SD7 may be disposed on the second interlayer insulation layer ILD2. The sixth source drain metal layer SD6 may be a bridge portion electrically connected to the semiconductor layers ACT which are disposed apart from each other on the second buffer layer BUF2. The seventh source drain metal layer SD7 may be a portion which configures a data line of an adjacent subpixel.

A first light emitting layer EL(R) and a second light emitting layer EL(G) divided or separated from each other by the bank layer BNK may be disposed on the anode electrode layer ANO. In the subpixel illustrated in FIG. 15, an example where an emission area emitting light has a diamond shape instead of a tetragonal shape (or a rectangular shape) is merely illustrated, and the present disclosure is not limited thereto.

As seen through the above descriptions, the first reference line VREF1 and the second reference line VREF2 are disposed on different layers and may be electrically connected to each other by a contact hole CH disposed in an overlap region therebetween (see FIG. 13). Also, the first reference line VREF1 and the second power line EVSS may be disposed on the same layer and may be formed by a source drain metal layer which configures a source electrode and a drain electrode of a transistor included in a subpixel SP. The source drain metal layer may include the first reference liner VREF1, the second power line EVSS, the source electrode and the drain electrode. Each of the first reference liner VREF1, the second power line EVSS, the source electrode and the drain electrode may be disposed in (e.g., be a part of or be formed out of) the source drain metal layer.

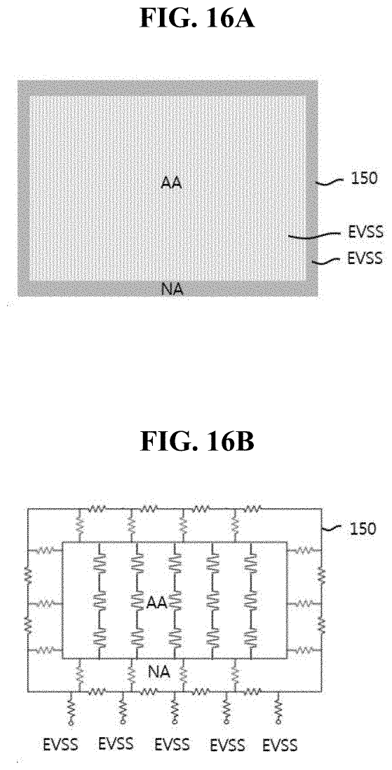

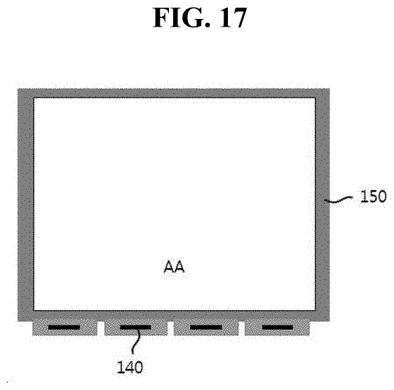

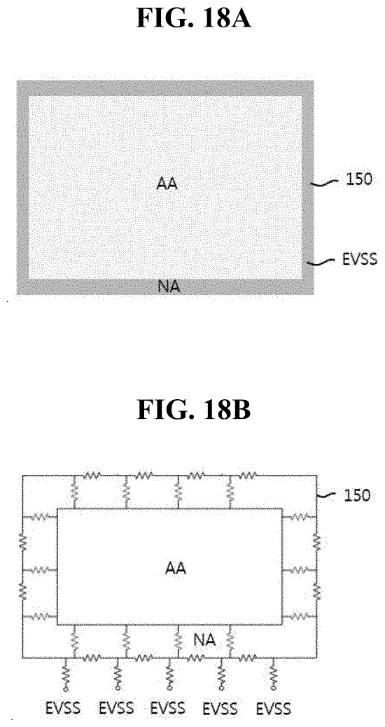

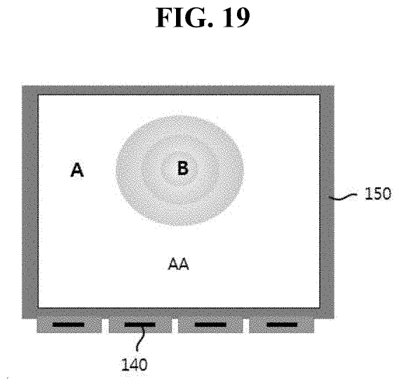

FIGS. 16A, 16B and 17 are diagrams for describing an arrangement structure of a line according to an embodiment of the present disclosure and an advantage based thereon, and FIGS. 18A, 18B and 19 are diagrams for describing an arrangement structure of a line according to an experiment example and a disadvantage based thereon. For reference, in a case where a structure of FIG. 16A is illustrated in circuit, the structure is as illustrated in FIG. 16B, and in a case where a structure of FIG. 18A is illustrated in circuit, the structure is as illustrated in FIG. 18B.

As illustrated in FIGS. 16A, 16B and 17, in an embodiment of the present disclosure, a second power line EVSS may be disposed in a display area AA and a non-display area NA of a display panel 150. The second power line EVSS may be disposed in the non-display area NA to surround all surfaces of the display area AA, and moreover, may be disposed in the display area AA to have a mesh shape.

In an embodiment of the present disclosure, the second power line EVSS having a mesh shape may be disposed in the display area AA, thereby solving a problem where a second source voltage increases (EVSS rising) when the display panel 150 is manufactured to have a certain size or shape or is driven by a certain method. As a result, a uniform full white image may be wholly displayed on the display area AA.

However, as illustrated in FIGS. 18A, 18B and 19, in the experiment example, the second power line EVSS may be disposed in only the non-display area NA of the display panel 150 (and not in the display area AA) in terms of a structural characteristic of line arrangement. In the experiment example, because the second power line EVSS is disposed in only the non-display area NA of the display panel 150, it is difficult to solve a problem where a second source voltage increases (EVSS rising) when the display panel 150 is manufactured to have a certain size or shape or is driven by a certain method. As a result, due to a position-based luminance difference and a color coordinate difference caused by an increase in the second source voltage (EVSS rising), it may be difficult to display a uniform full white image at a first point A and a second point B of the display area AA. For example, the second point B may cause a reddish phenomenon when optical compensation is being performed.

In the present disclosure, there may be an effect where repair is smoothly and easily performed when disconnection or short circuit occurs in some lines, on the basis of a mesh-type reference line. Also, in the present disclosure, a second power line may be provided in a display area of a display panel, and thus, a problem where a second source voltage increases (EVSS rising) may be minimized or reduced in implementing a narrow bezel and a large screen of the display panel. Also, in the present disclosure, although the second power line is provided in the display area of the display panel, a pattern density may be reduced and a problem where a line (wiring) interval increases may be solved. Also, in the present disclosure, because a pattern density is reduced and a problem where a line (wiring) interval increases is solved, a problem may be minimized or reduced where crosstalk occurs and the performance of the display panel is reduced due to an increase in parasitic capacitor. Also, in the present disclosure, because a problem where the performance of the display panel is reduced is minimized or reduced, a uniform image may be realized without a position-based luminance difference and a color coordinate difference. Also, in the present disclosure, because a pattern density is reduced and an increase in line interval is minimized or reduced, a problem may be solved where a production yield is reduced due to short circuit between lines and short circuit caused by particles.

The effects according to the present disclosure are not limited to the above examples, and other various effects may be included in the specification.

While the present disclosure has been particularly shown and described with reference to embodiments thereof, it will be understood by those of ordinary skill in the art that various changes in form and details may be made therein without departing from the spirit and scope of the following claims.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display apparatus comprising:
a display panel including a display area and a non-display area;
a first reference line arranged in a first direction in the display area;
a second reference line arranged in a second direction transverse the first direction in the display area and electrically connected to the first reference line; and
a power line arranged in the first direction in the display area and disposed between at least two of the first reference lines.

2. The light emitting display apparatus of claim 1, wherein at least one of the first reference line and the second reference line is disposed on a layer which differs from the power line.

3. The light emitting display apparatus of claim 1, wherein the second reference line is disposed on a layer which differs from the first reference line and the power line.

4. The light emitting display apparatus of claim 1, wherein the first reference line and the power line are disposed in a source drain metal layer, the source drain metal layer being in a transistor included in a subpixel of the display panel.

5. The light emitting display apparatus of claim 4, wherein the second reference line is disposed in a semiconductor layer, the semiconductor layer being in a transistor included in a subpixel of the display panel.

6. The light emitting display apparatus of claim 4, wherein the first reference line and the power line are disposed between an interlayer insulation layer and a planarization layer disposed on a layer which is higher than the second reference line.

7. The light emitting display apparatus of claim 5, wherein the second reference line is disposed between a buffer layer and a gate insulation layer disposed on a layer which is lower than the first reference line and the power line.

8. The light emitting display apparatus of claim 1, wherein the power line comprises a lower level power line, and
wherein a power level of the lower level power line is lower than a selected power level.

9. The light emitting display apparatus of claim 8, further comprising another power line whose power level is higher than the selected power level.

10. The light emitting display apparatus of claim 1, wherein the first reference line and the second reference line are arranged as a mesh type.

11. The light emitting display apparatus of claim 1, wherein the power line is disposed to have a mesh shape in the display area.

12. A light emitting display apparatus comprising:
a buffer layer disposed on a substrate;
a lower reference line in a semiconductor layer disposed on the buffer layer, the lower reference line being arranged in a horizontal direction in a display area of the substrate;
at least one insulation layer disposed on the lower reference line;
an upper reference line disposed on the at least one insulation layer, arranged in a vertical direction in the display area of the substrate, and electrically connected to the lower reference line; and
a power line disposed on the at least one insulation layer and arranged in the vertical direction in the display area of the substrate.

13. The light emitting display apparatus of claim 12, wherein the upper reference line and the power line are disposed apart from each other on the at least one insulation layer and each is disposed in a source drain metal layer.

14. A method of manufacturing a light emitting display apparatus, the method comprising:
forming a buffer layer on a substrate;
forming a lower reference line in a semiconductor layer disposed on the buffer layer, the lower reference line being arranged in a horizontal direction in a display area of the substrate;
forming at least one insulation layer on the lower reference line;
patterning a first source drain metal layer disposed on the at least one insulation layer and arranged in a vertical direction in the display area of the substrate to form an upper reference line electrically connected to the lower reference line; and
patterning a second source drain metal layer disposed on the at least one insulation layer and arranged in the vertical direction in the display area of the substrate to form a power line apart from the upper reference line.
